(19) United States
(12) Patent Application Publication
(10) Pub. No.: US 2026/0275506 A1
(43) Pub. Date: Sep. 17, 2026

(54) RBSIC COMPONENT COMPRISING AN SIC COATING, USE OF AN SIC COATING, AND METHOD FOR MANUFACTURING A COMPONENT

(71) Applicants: Lars SCHNETTER, Wimbach (DE); Philipp GINGTER, Mönchengladbach (DE); Clara MINAS-PAYAMYAR, Düsseldorf (DE); Dustin KERSBERG, Lindlar (DE); Detlef BRANDS, Meerbusch (DE)

(72) Inventors: Lars SCHNETTER, Wimbach (DE); Philipp GINGTER, Mönchengladbach (DE); Clara MINAS-PAYAMYAR, Düsseldorf (DE); Dustin KERSBERG, Lindlar (DE); Detlef BRANDS, Meerbusch (DE)

(21) Appl. No.: 19/474,436

(22) PCT Filed: May 3, 2023
(86) PCT No.: PCT/EP2023/061653

§ 371 Date: Oct. 10, 2025

(51) Int. Cl. C23C 16/32; C23C 14/06

(52) U.S. Cl. CPC C23C 16/325; C23C 14/0635

(57) ABSTRACT

A component comprising a component body made of a reaction bonded silicon carbide (RBSiC) is disclosed, the component body having a body surface at least partially coated with a coating, the coating comprising silicon carbide (SiC) with a layer thickness of at least 25 μm. A use of such an SiC coating and a method for manufacturing a component comprising an SiC coating are disclosed.

### CROSS-REFERENCE TO RELATED APPLICATIONS

This is a national phase application under 35 U.S.C. 371 of International Application No. PCT/EP2023/061653 filed May 3, 2023, entitled “RBSIC COMPONENT COMPRISING AN SIC COATING, USE OF AN SIC COATING, AND METHOD FOR MANUFACTURING A COMPONENT,” the contents of which being incorporated by reference in their entirety herein.

### TECHNICAL FIELD

The disclosure relates to a component having a component body made of reaction-bonded silicon carbide (RBSiC), to a use, and to a method for producing a component having a component body made of reaction-bonded silicon carbide (RBSiC).

### BACKGROUND

A variety of components made of reaction-bonded silicon carbide (RBSiC) are known from the prior art. RBSiC has good temperature stability up to 1380° C., low thermal expansion coefficient, high stiffness (elasticity modulus>380 GPa), and high hardness. For this reason, products based on RBSiC are employed in numerous heavy-duty segments, including burners and radiant tubes in industrial furnaces, rollers for roller furnaces, firing aids for the sintering of porcelain and cordierite, and slide ring packings. A further advantage of RBSiC is its low shrinkage (<1%) in the production process, enabling the production of very large components with high dimensional integrity.

Nevertheless, there are many applications for which the present properties of RBSiC are not enough. In such applications, components made of sintered silicon carbide (SSiC) are fabricated in the related art. SSiC relative to RBSiC has higher hardness, greater strength, better chemical resistance, and higher temperature stability. A disadvantage is the high complexity when producing components from SSiC, since its shrinkage in the production process is substantially greater than that of RBSiC. The SSiC material shrinks more than 10% in the sintering process, typically around 20%. This results in difficulty, especially in the context of the fabrication of large components, owing to cracking, component stresses, and lack of dimensional integrity. A high production reject rate is the result.

In practice, therefore, for relatively large and complex components, RBSiC is predominantly the material of choice, provided the necessary product properties are achieved.

### BRIEF DESCRIPTION OF THE FIGURES

Further features, details and advantages of the disclosure are evident from the wording of the claims and also from the following description of an exemplary embodiment with reference to the drawing, in which

FIG. 1 shows a component having a component body made of RBSiC and having an SiC coating, specifically a cantilever paddle;

FIG. 2 shows a component having a component body made of RBSiC and having an SiC coating, specifically a carrying roller for roller furnaces;

FIG. 3 shows a component having a component body made of RBSiC and having an SiC coating, specifically a plate having a bionic stiffening structure on the reverse;

FIG. 4 shows a component having a component body made of RBSiC and having an SiC coating, specifically a hollow mirror; and

FIG. 5 shows a component having a component body made of RBSiC and having an SiC coating, specifically a frame structure.

### DETAILED DESCRIPTION

It is an object of the disclosure, therefore, to provide a solution with which large and cost-effective components in particular are achieved with low reject rates, high dimensional integrity, and increased hardness, greater strength, better chemical resistance and higher temperature stability relative to components made of RBSiC. An objective, moreover, is to achieve components lighter than with RBSiC that have comparable strengths, so that there is optionally a reduction in resource usage, so contributing to improving the environmental footprint and savings in costs of materials.

Main features of the disclosure are indicated in the characterizing clause of claim 1 and also claims 23 and 24. Embodiments are subjects of claims 2 to 22 and 25 to 29.

For a component having a component body made of a reaction-bonded silicon carbide (RBSiC), the disclosure provides that the component body has a body surface coated at least partly with a coating, wherein the coating consists of silicon carbide (SiC) having a coat thickness of at least 25 μm.

An advantage of this is that the component body made of RBSiC can first of all, as known, be produced with high dimensional integrity and low reject rate. The coating of the body surface with SiC increases the surface hardness and chemical resistance in the region of the coated body surface. Locally and hence overall, moreover, the coating increases the component strength, as the SiC coating acts, for example, like a kind of exoskeleton or an exo-shell relative to the component body. Because the coefficients of thermal expansion (CTEs) of the RBSiC and of the SiC coating are close to one another (differing by less than 1*10\hat{ }−5 W/mK), it is also possible to coat very large RBSiC components without coat detachment and in the integrated system to achieve particular strength properties. In particular, it is also possible in this way to provide components which are particularly lightweight and yet high-strength. The usage of RBSiC material can be reduced and is compensated, so to speak, by the SiC coating. Starting from as low as 25 μm, a coating is able to achieve effective protection against furnace atmospheres and against consequent alloying.

The component body may in particular be a base body made of reaction-bonded silicon carbide (RBSiC). The base body may be produced from an initially still porous green body by infiltration with silicon (Si) and firing. The base body is then strong and gastight. The green body characterizes a pre-firing condition, with this preliminary stage consisting, for example, of SiC powder, carbon, and organic auxiliaries, and optionally silicon too. Infiltration and reaction take place subsequently.

According to one specific development, the coat thickness is at least 50 μm, optionally, at least 100 μm, optionally still at least 300 μm, and optionally at least 500 μm.

With increasing coat thickness, the component strength in particular is raised further and the coating has greater durability under chemical and mechanical load. At coat thicknesses>100 μm, better>300 μm, efficient protection against abrasive particles, for example, is formed by the SiC coating. SiC synthesized via vapor deposition, for example, typically has strength values of >500 MPa. Hence it was possible at 120 μm SiC coat thickness to raise the characteristic strength of standardized RBSiC flexural bars by 10% relative to the uncoated quality; at 600 μm SiC coat thickness, a strength increase by 50% was achievable. In absolute numbers, this denotes an increase in the characteristic flexural strength to 306 MPa in the case of the coated variant, in comparison to 208 MPa in the case of uncoated test specimens.

According to one closer configuration, the body surface has subregions oriented in different spatial directions, wherein the coating is disposed at least in subregions which point in at least two of six spatial directions. This contributes in particular to a multidimensional strength increase. Depending on application, components receive different loadings. In the course of component design, the regions of the component body having the most critical loadings can be identified and reinforced by means of the SiC layer.

In the case of multidimensionally loaded components, then, it is particularly useful to employ the SiC coating in multiple spatial directions for component reinforcement. It is optionally possible for this purpose that the coating is disposed in subregions which point in at least three of the six spatial directions, optionally at least four of the six spatial directions, optionally five of the six spatial directions, and optionally in all six spatial directions.

Additionally, there are optional component configurations in which the coating is disposed at least in a subregion of the body surface which belongs to a stiffening structure of the component body, as for example a stiffening structure from the group of rib, web, strut, tension bar, compression bar, honeycomb, rim or thickening.

In one specific development, the stiffening structure is a skeleton, a scaffold, or a bionic structure.

With regard to the coating, in some embodiments, the silicon carbide (SiC) of the coating has a purity of 98%, optionally 99% and optionally 99.9%. The purity can be determined by way of XRF (X-ray fluorescence) analysis and also ICP (inductively coupled plasma) spectroscopy. Where such a high-purity SiC coating is used, relatively inexpensive RBSiC can be used for the component body, having for example a purity<99% (sum total of Si and SiC), or having impurities>100 ppm or even >1% in the semiconductor segment (particularly diffusion furnaces). A coating with a minimum thickness of 50 μm ensures that no impurities travel from the substrate material onto the sensitive Si wafers. Accordingly, for example, paddles, wafer boats, reactor tubes or the like can be produced in an advantageous way. Specifically, it is possible accordingly to use starting raw materials, i.e., essentially SiC powder and Si powder, having an overall impurity level of more than 0.5%, but optionally less than 5%, optionally less than 3% and optionally less than 1%, without contaminating the wafers in the process.

The coating optionally has a coat thickness of not more than 2 mm. These coat thicknesses can still be applied homogeneously and without cracking by technical means, so that they accomplish desired functions. Accordingly, the ratio of coating benefit to production costs is favorable. In relation to the component body, therefore, the predominant fraction of material weight can consist of RBSiC (RBSiC relative to SiC>70%, optionally>80%, and optionally>95%).

A further optional parameter of the coating is that it has a particle size which is not more than 20 μm, optionally not more than 10 μm, optionally not more than 7 μm, optionally still not more than 4 μm and optionally not more than 1 μm. This results in good mechanical properties for the coating. The advantage is that the strength of the component is well above the strength of the uncoated component body because of the appropriate particle sizes of the coating.

At the preliminary stage, the particle size of the starting powder for the component body can be determined by laser diffraction particle size analysis or measurement by laser granulometry on the raw material. After the component body and the coating have been produced, and on the later component, the particle sizes may be calculated by section and optical microscopy or electron microscopy.

It proves useful for the component body to have a mean particle size, more particularly the mean particle size D50, of at least 25 μm, optionally at least 50 μm, optionally at least 70 μm, optionally still at least 90 μm and optionally at least 100 μm. This D50 value indicates the mean particle size. D50 means that 50% of the particles are smaller than the indicated value. The maximum particle size of the component body ought to be 700 μm.

According to one specific embodiment, the component body has a purity level of less than 99% silicon carbide (SiC) auf. This makes it inexpensive to produce. Elevated requirements with regard to the purity of material can be produced in the region of the body surface by means of a suitable coating.

The component proves particularly advantageous if the component body is at least partly a 3D printed part or a green body of the component body is based at least partly on a 3D printed part. Such a 3D printed part may be notable in particular for having a body surface which has coat steps along application coats. Such a part is therefore evident from such steps. The advantage of the 3D printed part is that complex structures made of RBSiC can be formed efficiently, particularly by subsequently subjecting a printed green body to infiltration firing. These complex structures may be subsequently improved in terms of strength, temperature stability, hardness and chemical resistance. With the SiC-coated RBSiC component body, materials properties are achieved that are akin to those of an SSiC component, even for components which on account of their shape cannot be produced from SSiC at all. In combination with the 3D printing, numerous new design features can be implemented in order, for example, to increase the loading density or to reduce the thermal mass. Here it has previously been necessary to employ high-purity RBSiC, which is expensive and complicated to produce, with a concomitant restriction on design freedom.

The 3D printing method is optionally a powder bed-based method. The process of powder bed-based 3D printing typically results, especially after infiltration firing, in qualities of RBSiC which in comparison to RBSiC fabricated conventionally, i.e., for instance, via extrusion, compression molding or slip casting, exhibit a lower flexural strength of <250 MPa. For component bodies produced in a 3D printing method, therefore, because of the SiC coating, the positive effect of the increase in strength is greater, relatively, than for component bodies made from material with an already high initial strength.

It is true that advantages are achievable even with small coated area proportions. The strength-enhancing and hardness-increasing properties, however, are manifested particularly for a relatively high coated area proportion of the component body. Accordingly, configurations are therefore possible in which at least 70%, optionally 80%, optionally at least 85%, optionally still at least 90%, optionally still at least 95%, and optionally 100% of the body surface is coated with the coating.

The coating may specifically be a CVD coat (chemical vapor deposition) or PVD coat (physical vapor deposition). CVD coats of SiC reduce the propensity to precipitate impurities in the case of RBSiC, quartz or SSiC and also improve the corrosion durability of the component body. Accordingly, the coating may be an anticorrosion coat.

High strength is achieved with the coating in particular if the coating is configured coherently. With this configuration it is possible in particular to achieve a homogeneous microstructure in the coating.

The disclosure is suitable in particular for the cases in which
the component is a satellite carrier; or
the component is an antenna carrier; or
the component is a roller for a continuous furnace or roller furnace; or
the component is a component part or workpiece holder of a diffusion furnace, as for example a paddle, baffle boat, tube or liner for a diffusion furnace; or
the component is a burner or radiant tube in a furnace; or
the component is a slide ring or a mating ring of a slide ring packing.

In the case of satellite carriers and antenna carriers, the high strength for low weight, in particular, is a key advantage, especially for space applications. The high hardness for low abrasion on the part of the coating gives slide ring packings particularly low wear. In the case of the furnace applications, the chemical resistance and temperature stability in particular are a considerable step forward.

The disclosure relates in a further aspect to the use of a coating of silicon carbide (SiC) having a coat thickness of at least 25 μm for coating a body surface of a component body, made of a reaction-bonded silicon carbide (RBSiC), of a component, for:
a) increasing the hardness of the body surface of the component; and/or
b) increasing the strength of the component; and/or
c) for improving the chemical resistance of the body surface of the component; and/or
d) for increasing the temperature stability of the component.

The advantageous coating of a component body made of RBSiC with SiC hence leads, even in the case of large components, to low reject rates, high dimensional integrity, and to greater strength, increased hardness, better chemical resistance and higher temperature stability relative to components made of RBSiC. The use of the coating of silicon carbide (SiC) having a coat thickness of at least 25 μm contributes to reduced materials usage and to a component configured and fabricated with sparing use of resources and with particularly low weight.

The use in accordance with the disclosure may optionally encompass in each case the individual apparatus features of the component as it is specified above and below. In particular, the use may optionally also relate to the technical features of the coating, as it is specified above and below, in isolation from the component and the component body.

The disclosure further relates to a method for producing a component, comprising the following steps:
a) producing a component body by
   a. fabricating a powder-based green body from silicon carbide (SiC) and a carbon source;
   b. performing a reaction firing with infiltration of the green body with silicon (Si) to generate a base body made of reaction-bonded silicon carbide (RBSiC);
b) at least partly coating a body surface of the component body with a coating of silicon carbide (SiC) having a coat thickness of at least 25 μm.

The methodologically advantageous coating of a component body or base body made of RBSiC with SiC hence leads, even in the case of large components, to low reject rates, high dimensional integrity, and to greater strength, increased hardness, better chemical resistance and higher temperature stability relative to components made of RBSiC. The method contributes to less materials usage and to a component configured and fabricated with sparing use of resources and with particularly low weight.

The carbon source in the powder-based green body may be introduced, for example, by an impregnating step for incorporating free carbon (C) in a powder-based preliminary base body made of silicon carbide (SiC).

The method of the disclosure may optionally be implemented in each case in such a way that the individual apparatus features of the component as is specified above and below are achieved.

In particular, the method may provide that the body surface has subregions oriented in different spatial directions, wherein the coating is applied at least in subregions which point in at least two of the six spatial directions. This contributes to improved component properties in multiple spatial directions.

According to one configuration of the method, the body surface of the component body that is intended for coating is abraded at least partly or completely prior to coating. This allows the planarity of the coating to be improved. This in turn improves the strength of the coating under flexural and tensile stresses and the like, and prevents cracking in the coating. Abrading has the effect in particular of preventing surface roughnesses from exerting notch effects on the coating. In this way, moreover, a lower coat thickness can be selected, which is more cost-effective.

The green body is optionally fabricated by printing in a 3D printing method. The carbon source in this case may optionally also be introduced after the 3D printing, by impregnation of the printed part, for example. Complex and bionic structures can be generated by this technique. The 3D printing method is optionally a powder bed-based method. The printing ought to be followed by an infiltration process and firing, with which the printed green body is infiltrated with silicon (Si). This increases the density and strength of the component body.

It proves particularly advantageous if coating is accomplished by a CVD method (chemical vapor deposition) or a PVD method (physical vapor deposition). Complex component structures can thus be coated homogeneously in a simple way. Regions of the component body that are not intended to be coated may optionally be covered by masks.

In particular, the method may provide for the coating to be configured in accordance with the description above and below. Reference may be made at this point to the advantages indicated there in each case.

The advantageous disclosure will first be set out in more detail via a number of examples:

### RBSiC Rollers

In the case of the coating of RBSiC rollers with at least 25 μm, optionally at least 50 μm CVD-SiC, it is possible to protect them from aggressive media of the kind occurring, for example, during the calcination of cathode material for fabrication of lithium-ion batteries. Materials frequently used here include cobalt, nickel, aluminum, manganese and lithium. When conventional RBSiC rollers are used, these materials tend to form alloys with the Si, so generating partially eutectics and hence reducing the durability. The abrasion of the frequently used cordierite or mullite crucibles also generates highly abrasive particles, which attack the rollers and reduce the lifetime. Furthermore, the aggressive furnace atmosphere formed on calcination of the materials reduces the lifetime of the RBSiC rollers.

A coating>25 μm or better>50 μm is already able to achieve effective protection against the furnace atmosphere and against formation of alloys; at>100 μm, better>300 μm, moreover, efficient protection against the abrasive particles is formed. All in all, the durability of the rollers can be substantially prolonged in this way. At the same time, components can be fabricated at significantly more favorable expense for the component body made of RBSiC through the use of a lower-purity powder. The high coat thickness also helps to raise the strength of the rollers and hence the use of lower cross sections—a reduction by 10%, for example—than would be the case for RBSiC. The thermal mass in the furnace is reduced by these means. Pure silicon carbide rollers (SSiC), which can be utilized alternatively, would be significantly more expensive than SiC-coated RBSiC component bodies.

### Components for the Space Industry

A further very advantageous application case for the disclosure is the space industry. In light of the complex load initiation scenarios and the need for extremely low mass, i.e., for optimized designs, the possibility of 3D printing of the green body is exceptionally advantageous here in particular. Accordingly, bionic structures can be created, combining high stiffness and strength with low weight (e.g., 30% less than for a comparative aluminum structure). In view of the strength increase resulting from the applied SiC coat, in a CVD method, for example, it is possible either to reduce the mass of the structures (reduced wall thicknesses, more intricate webs, et cetera) or to further reinforce existing designs. This effect can also be employed for simple geometries from other shaping methods. Here it is advantageous that the highest loads relevant for ceramics, in the form of tensile stresses, always occur in the exterior of the component (the so-called outer fibers). Where these exterior volumes consist of a material of higher strength, the overall component strength is increased. The use of a fine CVD-SiC coating with particle sizes<20 μm, better<10 μm, even better<1 μm in high purity (>95%, better>99%) enables a significant boost to the strength of the overall component.

### Cantilever Paddle for Diffusion Furnace Utilization

A ceramic body based on a reaction-bonded composite material, consisting substantially of SiC and also free Si, is produced as follows by means of a powder bed-based 3D printing method. It is constructed layer by layer starting from an amorphous collective of particles consisting of SiC, the powder being based on a particle size distribution known from technical refractory ceramics by the designation 100/F and thus having characteristic values of d10=75 μm, d50=115 μm, d90=160 μm. The selective solidification of the particles takes place at the locations dictated by an underlying CAD model, through the dropwise introduction of an organic binder, optionally furan resin, which is applied via inkjet printheads. The CAD model used here, corresponding to the final component geometry, allows the generation of structures with complex shaping. Following these two individual steps, the construction field plane is lowered by a pre-defined layer thickness, amounting for example to 300 μm. This sequence of steps is repeated iteratively until the layer-by-layer implementation of the CAD model is complete. The preliminary body obtained in this way, with complex shaping, has a porosity of around 45% by volume and is subsequently infiltrated with an aqueous dispersion consisting of 30% by weight of colloidal carbon along with a dispersing assistant and a wetting agent. After a first impregnating operation, a ceramic preliminary body with complex shaping is obtained in this way, consisting to an extent of around 87% by weight of the original SiC powder and around 13% by weight of colloidal carbon. After a drying operation and a possible second impregnating step, this ratio changes to 79/21% by weight, and after a possible third impregnating step to 76/24% by weight. Depending on the size of the paddle, it may be useful to segment it in advance and print it in multiple parts, optionally two parts, and subsequently to carry out impregnation, as described here, and hence carbon enrichment. Following the respective drying, these partial segments must then be joined using organic auxiliaries (also known as assembling to the skilled person). A further production variant makes it possible, through the use of this joining technology, to segment the paddle in a manner in which one of the segments is produced using an alternative shaping method, such as an extrusion method, while the other, complexly shaped segment of the paddle is produced via the 3D printing method described here. This type of segmentation allows the production costs to be reduced, since each shaping method is used in accordance with the specific, cost-efficient advantages.

After a concluding drying operation, the complexly shaped preliminary body (green body) obtained via one of the production routes described here is converted by way of a reaction firing into a component body made of ceramic, based on a reaction-bonded composite material consisting substantially of SiC and free Si. On conclusion of this reaction firing, the join of the segments is no longer macroscopically detectable, thus resulting in a quasi-monolithic component. This component is subsequently coated with SiC by means of chemical vapor deposition (CVD), with the coat thickness of the optionally crystalline SiC being between 150 μm and 600 μm. The complexly shaped and also coated cantilever paddle thus obtained can be used for moving semiconductor “wafer boats” into and out of so-called diffusion furnaces or furnace reactors in general. A particular advantage, moreover, is that through the use of the CVD-SiC coat, raw SiC, Si and C materials of comparatively low purity can be used in producing the component body. Impurities in these raw materials typically comprise compounds of the elements V, Ti, Al, Fe, Na, Ca, Zr, Cu, Ni, with the total content of the impurities being up to 3% by weight, in isolated cases even up to 5% by weight. The CVD-SiC coat prevents these impurities penetrating the process chamber and so rules out contamination of the processed wafers.

### Carrying Roller for Roller Furnaces, Produced by Extrusion Methods

A ceramic body based on a reaction-bonded composite material consisting substantially of SiC and also free Si is produced as follows by means of an extrusion method. To this end, a plastic mass consisting substantially of SiC powder having a mean particle size of 40 μm, carbon having a mean particle size of<1 μm and also organic auxiliaries for plasticising the mass is extruded by means of an extruder with a pressing pressure of 40 to 55 bar to give an extrudate with a tubular cross section. The internal and external diameters here can be varied within a range from 10 mm to 80 mm, with a roller length of up to 5000 mm. After the end of shaping and after a concluding drying operation, the cylindrical preliminary body obtained via one of the production routes described here is converted by way of a reaction firing into a component body made of ceramic, based on a reaction-bonded composite material consisting substantially of SiC and free Si. This component body is subsequently coated with SiC by means of chemical vapor deposition (CVD), with the coat thickness of the optionally crystalline SiC being between 150 μm and 800 μm. The CVD-coated roller thus obtained, relative to conventional, uncoated rollers based on RBSiC, offers increased stiffness and thus reduced bowing under load and also an increased flexural strength and long-term stability. The coated roller also offers significantly increased corrosion resistance and also abrasion resistance and is therefore suitable particularly for use in roller furnaces for the calcining of CAM (cathode active material, i.e., RBSiC-corrosive metal oxides or phosphates based on lithium, nickel, cobalt, manganese, aluminum, iron and further elements).

### Mirror Produced Via 3D Printing Method

A ceramic body based on a reaction-bonded composite material consisting substantially of SiC and also free Si is produced by means of a powder bed-based 3D printing method. In this way, a hollow mirror structure is realized, which on the reverse side of the mirror face has a topologically optimized rib structure of complex shape, e.g., a honeycomb structure, thus giving the overall structure a high specific stiffness and strength, but at the same time minimizing the weight. Through the use of the above-described joining method and a subsequent reaction firing, it is possible for example to produce monolithic mirror structures having a diameter of up to 2500 mm. After the end of reaction firing, the mirror structure (a component body) based on a reaction-bonded composite material consisting substantially of SiC and free Si, optionally undergoes preliminary abrading and is subsequently coated with SiC by means of chemical vapor deposition (CVD), the coat thickness of the optionally crystalline SiC being between 150 μm and 2000 μm. The CVD-coated mirror structure thus obtained, in particular including coated stiffening or rib structure, offers increased specific stiffness and strength over conventional RBSiC structures. Furthermore, the at least substantially defect-free and pore-free SiC surface applied via CVD enables the realization of homogeneous optical surfaces having a square roughness of below 5 angstroms and a polishing quality of P2 or P3.

### Frame Structure Produced Via 3D Printing Method

A ceramic body based on a reaction-bonded composite material consisting substantially of SiC and also free Si is produced by means of a powder bed-based 3D printing method. In this way, a geometrically complex frame structure is realized, of the kind required, for example, for coordinate measuring machines and also in the semiconductor technology segment, especially for EUV lithography equipment. Through the use of the 3D printing method it is possible to realize geometries which are reduced in weight or even topologically optimized, in comparison to the conventional, subtractive fabrication. The use of the above-described joining method and of a subsequent reaction firing also makes it possible to produce particularly large, monolithic frame structures having an edge length of up to 2000 mm. After the end of reaction firing, the frame structure, based on a reaction-bonded composite material consisting substantially of SiC and free Si, is coated with SiC by means of chemical vapor deposition (CVD), the coat thickness of the optionally crystalline SiC being between 150 μm and 1000 μm. The CVD-coated frame structure thus obtained offers increased specific stiffness and strength over conventionally fabricated RBSiC frame structures. In this way, the exacting requirements imposed by applications in the segment of EUV lithography and of industrial metrology on the stiffness and strength of the frame structures of this kind are met in a particularly favorable way. Particularly in the context of frame structures for EUV lithography, the SiC-CVD coating is outstandingly suitable for preventing segregation of impurities, particles and so on from the substrate into the sensitive clean-room process environment. Particularly advantageous in this context is the high adhesive tensile strength of the SiC coat on the RBSiC substrate surface.

### Further Use Examples

Examples of the use of the disclosure described are frame structures for the mounting of optical components (known as “optical benches”), measuring systems or the like. There are further applications within the segment of mechanical engineering, examples being quills, air slide bearings, frame structures, etc. These components may then find application, for example, in CMM (coordinate measuring machine) systems, lithography equipment or similar precision machinery. A further possibility is the use of the coated components for wafer chucks, wafer tables or other components which come into contact with wafers. Here it is advantageous, in addition to the high mechanical strength, to focus on high purity of the coating (>99%, better>99.9%) and so to prevent contamination of the wafers. Enabled accordingly is the use of an RBSiC base material with potentially significantly lower purity for the component body.

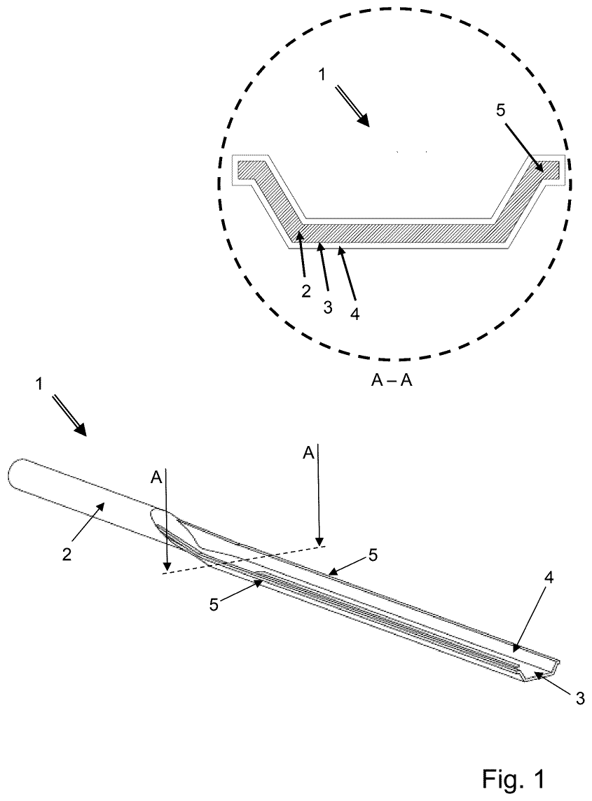

FIGS. 1 to 5 each show a component 1 having a component body 2 made of a reaction-bonded silicon carbide (RBSiC), said body comprising a body surface 3 coated completely with a coating 4. The coherently produced coating 4 of silicon carbide (SiC) has a coat thickness of at least 25 μm. Additionally, in each of FIGS. 1 to 5 a schematically represented section is represented at the marked position A-A, and contains the same reference numbers.

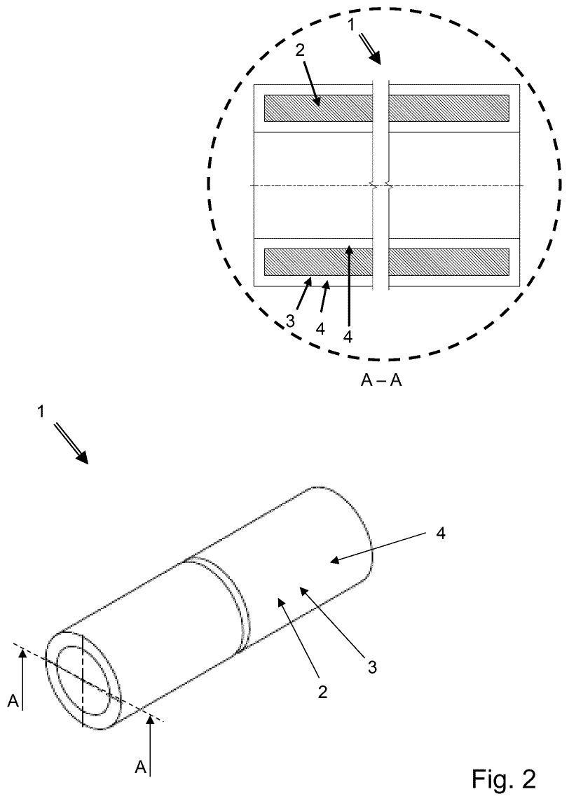

The body surface 3 can be seen to have subregions which are oriented in different spatial directions, with the coating 4 being applied in subregions which point in all six spatial directions. In accordance with FIGS. 1 and 3 to 5, these include subregions of the body surface 3 which belong to a stiffening structure 5 of the component body 2 in the form of ribs, rims or lattice structures. Only the carrying roller according to FIG. 2 has no such stiffening structures.

The coating 4 optionally has further properties as follows:
the silicon carbide (SiC) of the coating 4 ought to have a purity of 98%, optionally 99% and optionally 99.9%;
the coating 4 ought to have a coat thickness of not more than 2 mm;
the coating 4 ought to have a particle size which is not more than 20 ƒm, optionally not more than 10 μm, optionally not more than 7 μm, optionally still not more than 4 μm and optionally not more than 1 μm;
the coating 4 ought to be a CVD coat or PVD coat.

The component body 2 optionally has further properties as follows:
the component body 2 ought to have a mean particle size of at least 10 μm, optionally at least 50 μm, optionally at least 70 μm, optionally still at least 90 μm and optionally at least 100 μm; and
the component body 2 absolutely must have a degree of purity of less than 99%.

The left-hand region of the component 1 shown in FIG. 1 is embodied as a round bar or round tube. In the production method, this region of the component body 2 may be produced by continuous casting. The right-hand region of the component 1 has a more complex structure with angles, stiffening structures 5 and a hole. This part of the component body 2 may be a 3D printed part. The two parts of the component body 1 can be subsequently joined together by assembling and by reaction firing of the component body 2.

The component 1 according to FIG. 1 is a workpiece holder for a diffusion furnace, more particularly what is called a cantilever paddle. The coating 4 here serves simultaneously as anticorrosion coat, purity coat, strength coat, abrasion protection coat and temperature stability coat.

The component according to FIG. 2 is a carrying roller for diffusion furnaces. The component body 2 is encapsulated by the coating 4. The circumferential region of the coating 4 forms running faces of the roller. The internal parts of the coating 4 serve in particular for encapsulation in order to prevent precipitations from the component body 2, and to stiffen the component body 2.

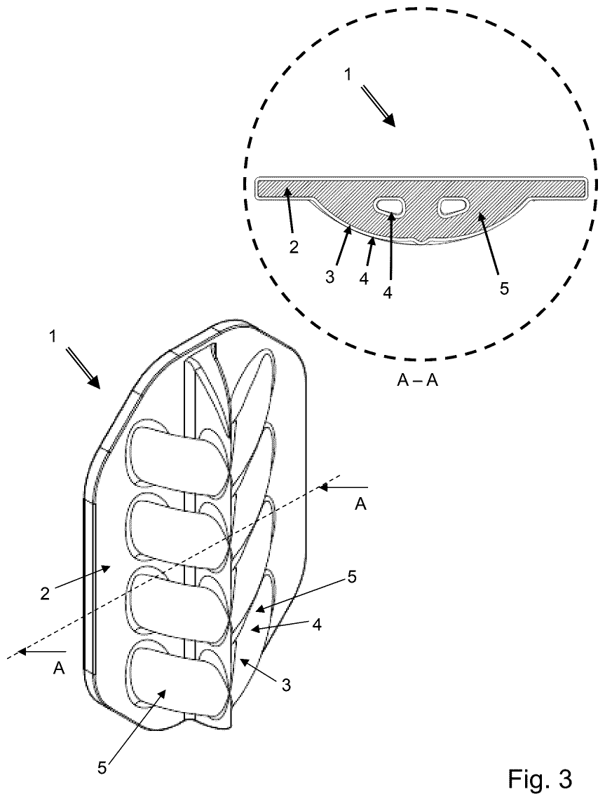

The stiffening structure 5 according to FIG. 3 likewise has external and internal regions of the coating 4. In this way, the arms of the stiffening structure 5 are stabilized on the inside and the outside with the coating 4.

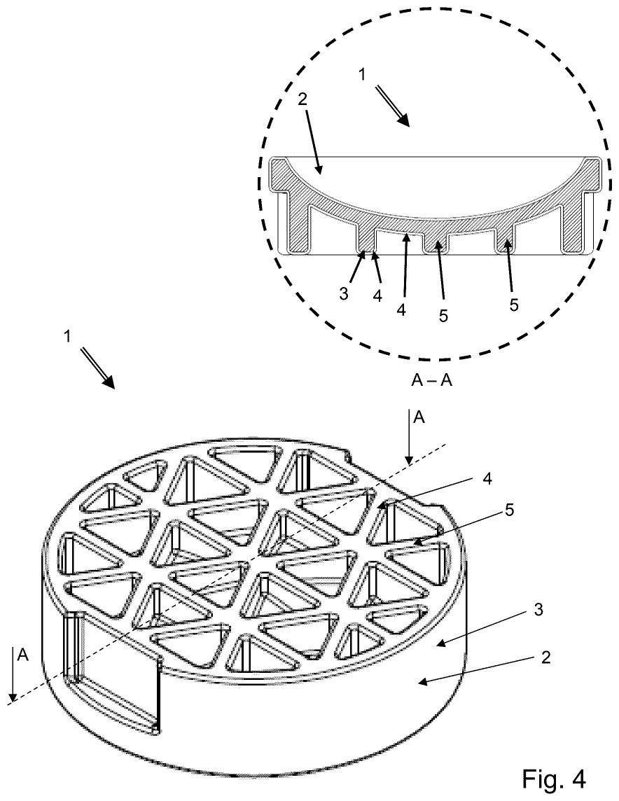

In the case of the hollow mirror according to FIG. 4, the coating of the reverse-side stiffening structure 5 is particularly important. It contributes to high thermal stability and shape conformity of the hollow mirror. The hollow face of the hollow mirror may-as represented-optionally likewise be provided with the coating 4.

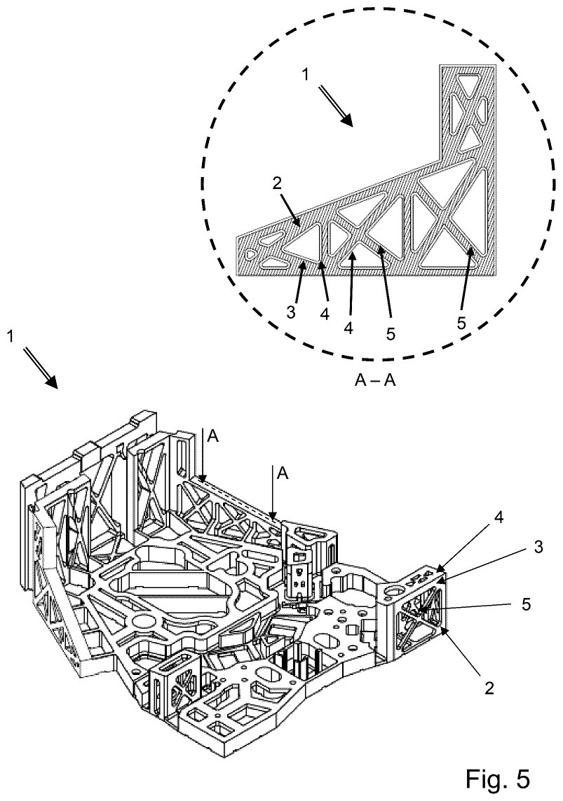

The frame structure according to FIG. 5 is a very complex component with extensive stiffening structures, stop faces and attachment points.

Rather than being confined to any of the embodiments described above, the disclosure may be modified in a diversity of ways.

All features and advantages evident from the claims, the description and the drawing, including construction details, spatial arrangements and method steps, may be essential to the disclosure both individually and in a very wide variety of combinations.

### List of Reference Signs

1 component
2 component body
3 body surface
4 coating
5 stiffening structure

1. A component having a component body made of a reaction-bonded silicon carbide (RBSiC), wherein the component body has a body surface coated at least partly with a coating, wherein the coating comprises silicon carbide (SiC) having a coat thickness of at least 25 μm.

2. The component as claimed in claim 1, wherein the coat thickness is at least 50 μm, at least 100 μm, at least 300 μm, or at least 500 μm.

3. The component as claimed in claim 1, wherein the body surface has subregions oriented in different spatial directions, wherein the coating is disposed at least in subregions which point in at least two of six spatial directions.

4. The component as claimed in claim 3, wherein the coating is disposed in subregions which point in at least three of the six spatial directions, at least four of the six spatial directions, five of the six spatial directions, or in all six spatial directions.

5. The component as claimed in claim 1, wherein the coating is disposed at least in a subregion of the body surface which belongs to a stiffening structure of the component body.

6. The component as claimed in claim 5, wherein the stiffening structure is a rib, a web, a strut, a tension bar, a compression bar, a honeycomb, a rim, a thickening, a skeleton, a scaffold, or a bionic structure.

7. The component as claimed in claim 1, wherein the silicon carbide (SiC) of the coating has a purity of 98%, 99%, or 99.9%.

8. The component as claimed in claim 1, wherein the coating has a coat thickness of not more than 2 mm.

9. The component as claimed in claim 1, wherein the coating has a particle size which is not more than 20 μm, not more than 10 μm, not more than 7 μm, not more than 4 μm, or not more than 1 μm.

10. The component as claimed in claim 1, wherein the component body has a mean particle size of at least 25 μm, at least 50 μm, at least 70 μm, at least 90 μm, or at least 100 μm.

11. The component as claimed in claim 1, wherein the component body has a purity level of less than 99% silicon carbide (SiC).

12. The component as claimed in claim 1, wherein the component body is at least partly a three-dimensionally (3D) printed part, or a green body of the component body is based at least partly on a three-dimensionally (3D) printed part.

13. The component as claimed in claim 1, wherein at least 70%, at least 80%, at least 85%, at least 90%, at least 95%, or 100% of the body surface is coated with the coating.

14. The component as claimed in claim 1, wherein the coating is at least one of a chemical vapor deposition (CVD) coat, a physical vapor deposition (PVD) coat, and an anticorrosion coat.

15. (canceled)

16. The component as claimed in claim 1, wherein:
the coating is configured coherently; and
the component (1) is a satellite carrier or an antenna carrier.

17-18. (canceled)

19. The component as claimed in claim 1, wherein:
the component is a roller for a continuous furnace or roller furnace;
the component is a component pa workpiece holder of a diffusion furnace;
the component is a burner or radiant tube in a furnace; or
component is a slide ring or a mating ring of a slide ring packing.

20-22. (canceled)

23. A method of use of a coating of silicon carbide (SiC) having a coat thickness of at least 25 μm for coating a body surface of a component body, made of a reaction-bonded silicon carbide (RBSiC), of a component, for:
a) increasing the hardness of the body surface of the component; and/or
b) increasing the strength of the component; or
c) improving the chemical resistance of the body surface of the component; or
d) increasing the temperature stability of the component.

24. A method for producing a component, comprising:
producing a component body by fabricating a powder-based green body from silicon carbide (SiC) and a carbon source; and performing a reaction firing with infiltration of the green body with silicon (Si) to generate a base body made of reaction-bonded silicon carbide (RBSiC); and
at least partly coating a body surface of the component body with a coating of silicon carbide (SiC) having a coat thickness of at least 25 μm.

25. The method as claimed in claim 24, wherein the body surface has subregions oriented in different spatial directions, wherein the coating is applied at least in subregions which point in at least two of the six spatial directions.

26. The method as claimed in claim 24, wherein at least one:
the body surface of the component body that is intended for coating is abraded at least partly or completely prior to coating;
the green body is manufactured by printing in a 3D printing method; and
the coating takes place by a chemical vapor deposition (CVD) method or a physical vapor deposition (PVD) method.

27-29. (canceled)
